(19) United States
(12) Patent Application Publication
(10) Pub. No.: US 2023/0387946 A1
(43) Pub. Date: Nov. 30, 2023

(54) BUTTON STRUCTURE OF A WIRELESS TRANSCEIVER AND MANUFACTURING METHOD THEREOF

(71) Applicant: WINMATE INC., New Taipei City (TW)

(72) Inventors: Ku-Ching LU, New Taipei City (TW); Yueh-Tsai WENG, New Taipei City (TW); Tsung-Cheng CHU, New Taipei City (TW)

(73) Assignee: WINMATE INC., New Taipei City (TW)

(21) Appl. No.: 18/198,996

(22) Filed: May 18, 2023

(30) Foreign Application Priority Data
May 30, 2022 (TW) 111120129

(51) Int. Cl. H04B 1/034; H05K 5/00

(52) U.S. Cl. CPC H04B 1/034; H05K 5/0004

(57) ABSTRACT

A button structure of a wireless transceiver and a manufacturing method thereof are provided. The button structure includes a housing, a first spring-back button, and a second spring-back button. The first spring-back button are integrally formed by double injection molding respectively. The first spring-back button and the second spring-back button are connected with the housing through insert injection molding. Thus, a manufacturer may produce the first spring-back button and the second spring-back button by a double injection molding machine in advance, and then combine the first spring-back button and the second spring-back button with the housing by the insert injection molding, so as to make the wireless transceiver with buttons of different colors.

### BACKGROUND OF THE INVENTION

### 1. Field of the Invention

The present invention relates to a button structure of a wireless transceiver, especially to a button structure of a wireless transceiver with buttons of different colors and a manufacturing method of the button structure.

### 2. Description of the Prior Art(s)

“Buttons” are widely used in various electronic devices like laptop computers, tablet computers, mobile phones and wireless transceivers, which are operated through the buttons. In the electronic devices for special occasions such as handheld wireless transceivers (also known as walkie talkie) for outdoor use, connection between each of buttons and a housing has to meet requirement of a predetermined Ingress Protection (IP) rating, so as to allow the electronic device to be waterproof and dustproof. Moreover, the buttons must have prominent colors that allow users to identify functions of the buttons according to the colors.

To the handheld wireless transceiver, the “Emergency Button” thereon must be red or orange, so that the users can identify and use immediately in an emergency. In addition, the number buttons of the handheld wireless transceiver may be white or gray, and the volume buttons or the other buttons with special functions are shown in blue, green or other colors for distinguishing. However, in order to meet the needs for buttons of different colors and the requirement of the IP rating, manufacturing cost of the handheld wireless transceiver has been increased.

Specifically, the most basic way to manufacture the housing and the buttons of the electronic device through injection molding is to use a double injection molding machine to form the housing with a first material having a first color and to form the buttons with a second material having a second color. When it is necessary to manufacture the housing with buttons of two different colors (for instance, a red button as an emergency button and a white button as a number button), an injection molding machine for injecting three materials is needed, and so on and so forth. The more colors of the buttons are required, the more materials are required in the injection molding process. The injection molding machines for injecting three, four or more materials are more complex and cost higher than the double injection molding machine, which is unfavorable to manufacturing of the electronic devices.

To overcome the shortcomings, the present invention provides a button structure of a wireless transceiver and a manufacturing method thereof to mitigate or obviate the aforementioned problems.

### SUMMARY OF THE INVENTION

The main objective of the present invention is to provide a button structure of a wireless transceiver. The button structure includes a housing, a first spring-back button, and a second spring-back button. The housing has a first button hole and a second button hole. The first spring-back button is mounted in the first button hole of the housing and has: at least one first pressing portion; a first surrounding portion disposed around the at least one first pressing portion, wherein the at least one first pressing portion and the first surrounding portion are made of the same material and have a first color; and a first elastic connecting portion connecting the at least one first pressing portion and the first surrounding portion, wherein the first spring-back button is integrally formed by double injection molding. The second spring-back button is mounted in the second button hole of the housing and has: at least one second pressing portion; a second surrounding portion disposed around the at least one second pressing portion, wherein the at least one second pressing portion and the second surrounding portion are made of the same material and have a second color; and a second elastic connecting portion connecting the at least one second pressing portion and the second surrounding portion, wherein the second spring-back button is integrally formed by double injection molding and the second color and the first color are different colors. The first spring-back button and the second spring-back button are connected with the housing through insert injection molding.

The main objective of the present invention is to provide a manufacturing method of the button structure of the wireless transceiver. The manufacturing method includes steps of:
a first preparation step: providing a first mold, injecting a first material into the first mold to form at least one first pressing portion and a first surrounding portion, and injecting a third material into the first mold to form a first elastic connecting portion, wherein the first surrounding portion is disposed around the at least one first pressing portion, the first material has a first color, the first elastic connecting portion connects the at least one first pressing portion and the first surrounding portion, and the at least one first pressing portion, the first surrounding portion and the first elastic connecting portion form a first spring-back button;
a second preparation step: providing a second mold, injecting a second material into the second mold to form at least one second pressing portion and a second surrounding portion, and injecting the third material into the second mold to form a second elastic connecting portion, wherein the second surrounding portion is disposed around the at least one second pressing portion, the second material has a second color, the second color and the first color are different colors, the second elastic connecting portion connects the at least one second pressing portion and the second surrounding portion, and the at least one second pressing portion, the second surrounding portion and the second elastic connecting portion form a second spring-back button; and
an assembling step: providing a third mold, placing the first spring-back button and the second spring-back button in the third mold, and injecting a fourth material into the third mold to form a housing.

A manufacturer may produce the first spring-back button and the second spring-back button by a double injection molding machine in advance, and then combine the first spring-back button and the second spring-back button with the housing by the insert injection molding, so as to make the wireless transceiver with buttons of different colors. The first spring-back button and the second spring-back button can be connected with the housing airtightly, such that the wireless transceiver is waterproof and dustproof. Since the double injection molding and the insert injection molding are normal manufacturing processes, complexity and cost of the machines and molds required for the double injection molding and the insert injection molding are lower than those of the injection molding machines for injecting three materials. Therefore, manufacturing cost of the wireless transceiver can be greatly reduced and the wireless transceiver is capable of meeting the requirement of a predetermined Ingress Protection (IP) rating.

Other objectives, advantages and novel features of the invention will become more apparent from the following detailed description when taken in conjunction with the accompanying drawings.

### BRIEF DESCRIPTION OF THE DRAWINGS

FIG. 1 is an operational perspective view of a button structure of a wireless transceiver in accordance with the present invention;

FIG. 2 is an operational exploded perspective view of partial components of the button structure of the wireless transceiver in FIG. 1;

FIG. 3 is a perspective view of a first spring-back button of the button structure of the wireless transceiver in FIG. 1;

FIG. 4 is an operational side view in partial section of the first spring-back button of the button structure of the wireless transceiver in FIG. 3;

FIG. 5 is a perspective view of a second spring-back button of the button structure of the wireless transceiver in FIG. 1;

FIG. 6 is an operational side view in partial section of the second spring-back button of the button structure of the wireless transceiver in FIG. 5;

FIG. 7 is a flowchart of a manufacturing method of a button structure of a wireless transceiver in accordance with the present invention; and

FIG. 8 is a flowchart of another manufacturing method of a button structure of a wireless transceiver in accordance with the present invention.

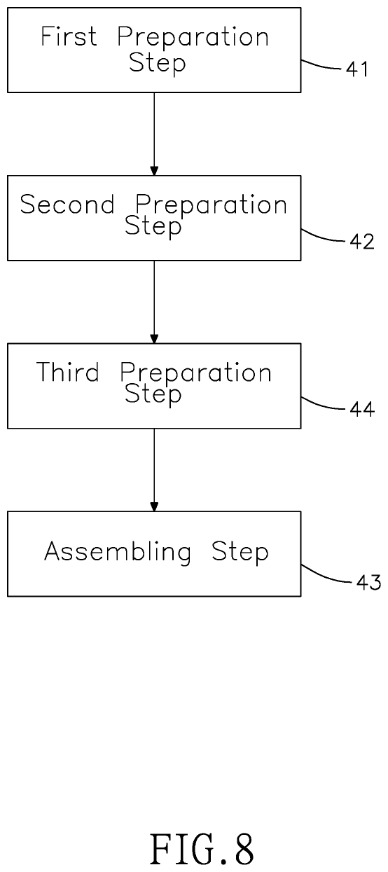

### DETAILED DESCRIPTION OF THE PREFERRED EMBODIMENTS

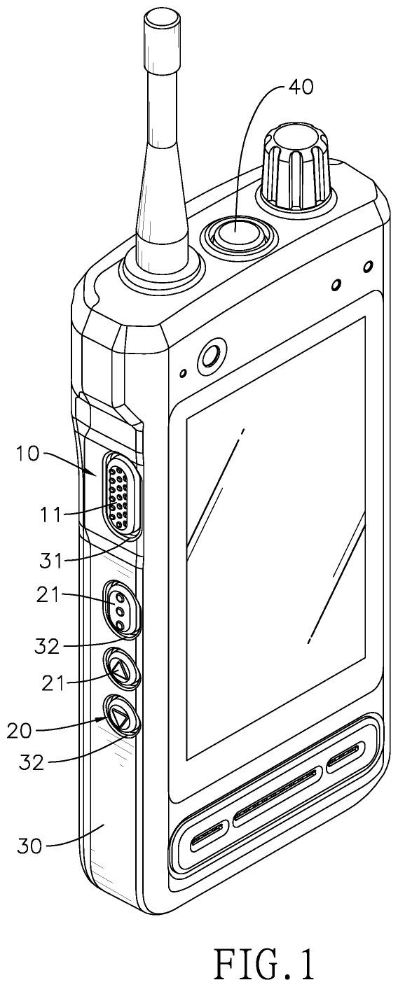

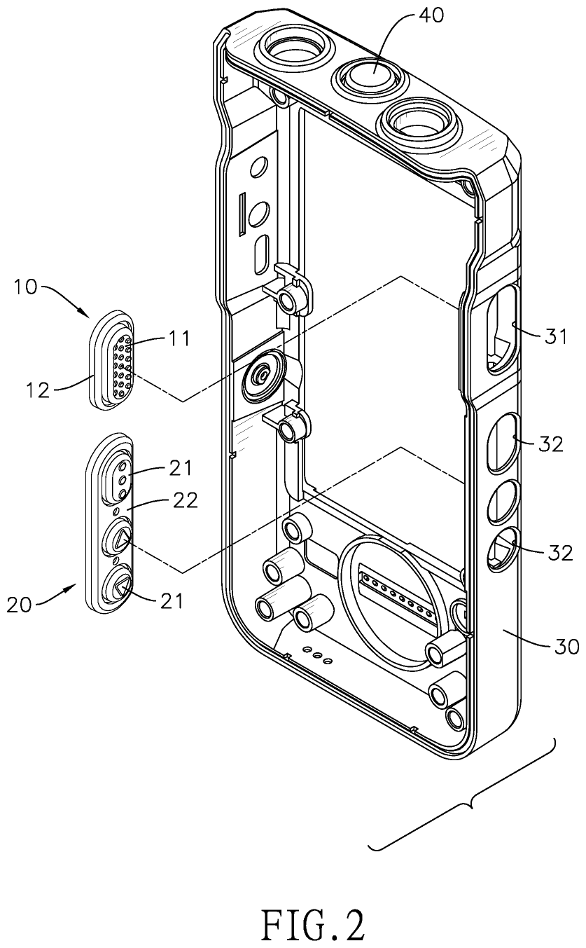

With reference to FIGS. 1 and 2, a button structure of a wireless transceiver with buttons of different colors comprises a housing 30, a first spring-back button 10, and a second spring-back button 20.

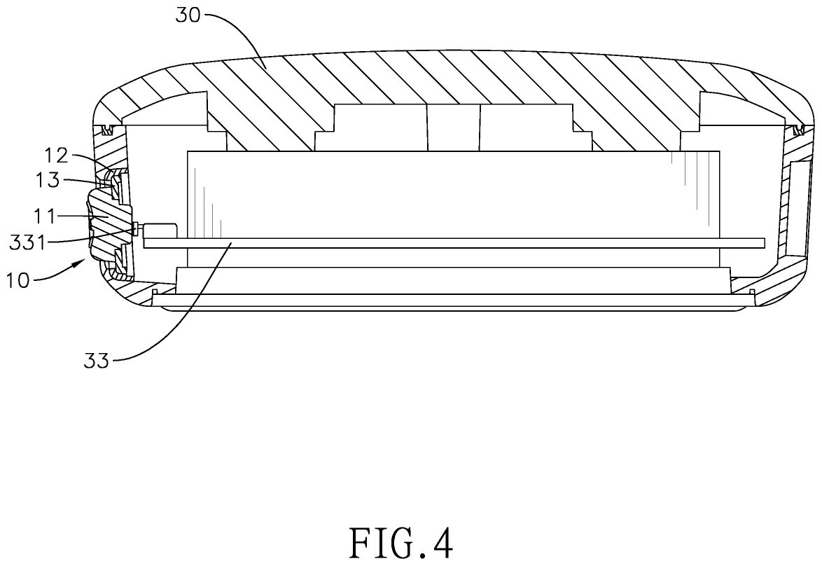

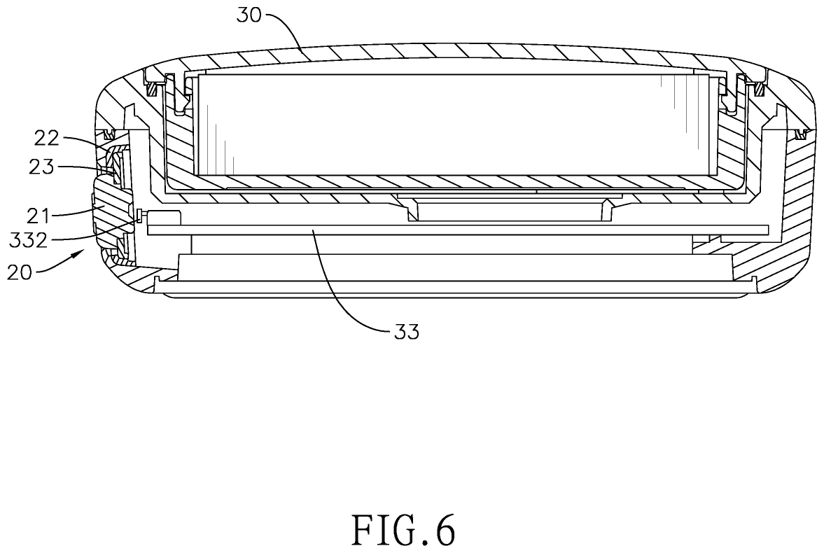

With further reference to FIGS. 4 and 6, the housing 30 has a first button hole 31, a second button hole 32 and an interior space. The first button hole 31 and the second button hole 32 are separately formed through the housing 30. The interior space is formed inside the housing 30 for mounting a communication module 33. The communication module 33 has at least one first triggering switch 331 and at least one second triggering switch 332.

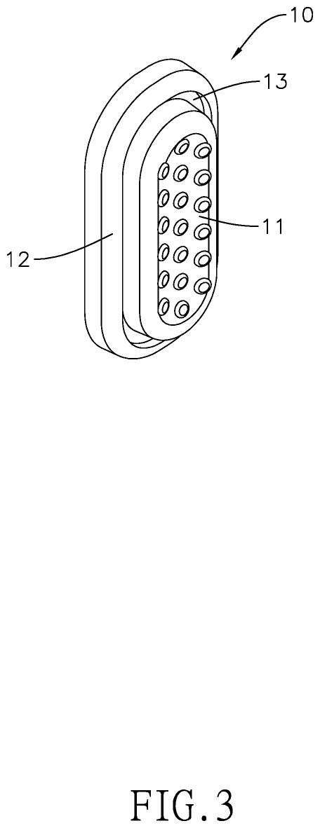

With further reference to FIGS. 3 and 4, the first spring-back button 10 is mounted in the first button hole 31 of the housing 30 and is connected with the housing 30 through insert injection molding. The first spring-back button 10 has at least one first pressing portion 11, a first surrounding portion 12, and a first elastic connecting portion 13. Each of the at least one first triggering switch 331 corresponds in position to a corresponding one of the at least one first pressing portion 11. The first surrounding portion 12 is disposed around the at least one first pressing portion 11 and is connected with a hole edge defined around the first button hole 31 of the housing 30. The at least one first pressing portion 11 and the first surrounding portion 12 are made of the same material and have a first color. The first elastic connecting portion 13 connects the at least one first pressing portion 11 and the first surrounding portion 12. The first spring-back button 10 is integrally formed by double injection molding. With the first elastic connecting portion 13 connecting the at least one first pressing portion 11 and the first surrounding portion 12, each of the first pressing portion 11 drives the first elastic connecting portion 13 to deform elastically when said first pressing portion 11 is pressed, such that said first pressing portion 11 moves relative to the first surrounding portion 12.

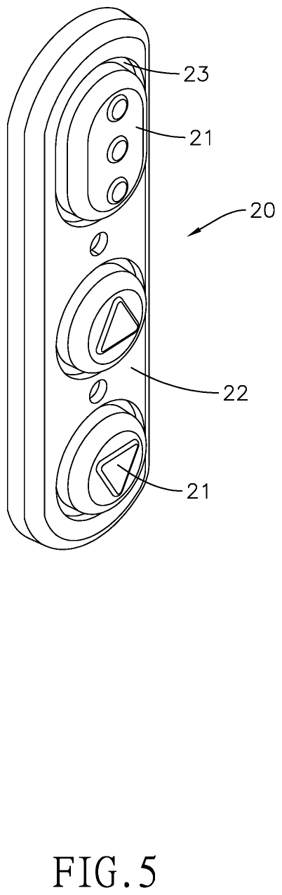

With further reference to FIGS. 5 and 6, the second spring-back button 20 is mounted in the second button hole 32 of the housing 30 and is connected with the housing 30 through insert injection molding. The second spring-back button 20 has at least one second pressing portion 21, a second surrounding portion 22, and a second elastic connecting portion 23. Each of the at least one second triggering switch 332 corresponds in position to a corresponding one of the at least one second pressing portion 21. The second surrounding portion 22 is disposed around the at least one second pressing portion 21 and is connected with a hole edge defined around the second button hole 32 of the housing 30. The at least one second pressing portion 21 and the second surrounding portion 22 are made of the same material and have a second color. The second elastic connecting portion 23 connects the at least one second pressing portion 21 and the second surrounding portion 22. The second spring-back button 20 is integrally formed by double injection molding, and the second color and the first color are different colors. With the second elastic connecting portion 23 connecting the at least one second pressing portion 21 and the second surrounding portion 22, each of the second pressing portion 21 drives the second elastic connecting portion 23 to deform elastically when said second pressing portion 21 is pressed, such that said second pressing portion 21 moves relative to the second surrounding portion 22.

In the preferred embodiment, the at least one first pressing portion 11 of the first spring-back button 10 includes one first pressing portion 11, and the at least one second pressing portion 21 of the second spring-back button 20 includes multiple second pressing portions 21.

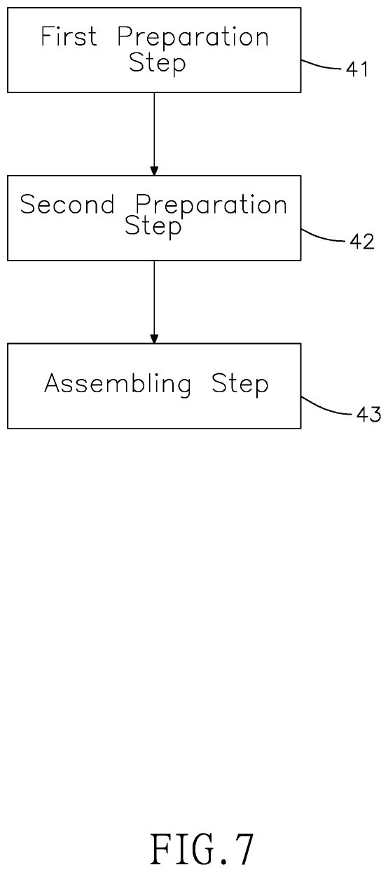

With further reference to FIG. 7, a manufacturing method of the button structure of the wireless transceiver with buttons of different colors includes a first preparation step 41, a second preparation step 42, and an assembling step 43.

In the first preparation step 41, a first mold is provided, a first material is injected into the first mold to form the at least one first pressing portion 11 and the first surrounding portion 12, and a third material is injected into the first mold to form the first elastic connecting portion 13. The first surrounding portion 12 is disposed around the at least one first pressing portion 11 and the first material has the first color. The first elastic connecting portion 13 connects the at least one first pressing portion 11 and the first surrounding portion 12. Accordingly, the at least one first pressing portion 11, the first surrounding portion 12 and the first elastic connecting portion 13 form the first spring-back button 10.

In the second preparation step 42, a second mold is provided, a second material is injected into the second mold to form the at least one second pressing portion 21 and the second surrounding portion 22, and the third material is injected into the second mold to form the second elastic connecting portion 23. The second surrounding portion 22 is disposed around the at least one second pressing portion 21 and the second material has the second color. The second color and the first color are different colors. The second elastic connecting portion 23 connects the at least one second pressing portion 21 and the second surrounding portion 22. Accordingly, the at least one second pressing portion 21, the second surrounding portion 22 and the second elastic connecting portion 23 form the second spring-back button 20.

It should be noted that the third material is used in the first preparation step 41 to form the first elastic connecting portion 13, and the third material is also used in the second preparation 42 to form the second elastic connecting portion 23. However, the third material can be another color which is different from the first color and the second color. In a preferred embodiment, the color of the third material can be a lighter color of the first color when the third material is used to form the first elastic connecting portion 13, and the color of the third material can be a lighter color of the second color when the third material is used to form the second elastic connecting portion 23. For example, if the first material, which forms the first pressing portion 11, is green, the third material used in the first preparation step 41 is laurel-green. Various modifications of colors can be made according to the practical need.

Specifically, the first material that forms the at least one first pressing portion 11 and the first surrounding portion 12 of the first spring-back button 10 may be a synthetic resin of Polycarbonate (PC) and Acrylonitrile Butadiene Styrene (ABS). The second material that forms the at least one second pressing portion 21 and the second surrounding portion 22 of the second spring-back button 20 may also be the synthetic resin of PC and ABS. The third material that forms the first elastic connecting portion 13 of the first spring-back button 10 and the second elastic connecting portion 13 of the second spring-back button 20 may be Thermal Plastic Rubber (TPR).

In the assembling step 43, a third mold is provided, the first spring-back button 10 and the second spring-back button 20 are placed in the third mold, and then a fourth material is injected into the third mold to form the housing 30.

That is, the first spring-back button 10 and the second spring-back button 20 are inserted in the third mold and then the fourth material is injected into the third mold to perform the insert injection molding. Thus, the first surrounding portion 12 of the first spring-back button 10 is airtightly connected with the fourth material and the second surrounding portion 22 of the second spring-back button 20 is also airtightly connected with fourth material. It should be noted that the housing 30 is normally made of hard material (i.e. the fourth material) in order to provide good protection for electronic components that are mounted inside the wireless transceiver. In the preferred embodiment, the fourth material has material properties that are similar to that of the first material for forming the first surrounding portion 12, or the fourth material has material properties that are similar to that of the second material for forming the second surrounding portion 22. Thus, during the insert injection molding, it would be easier to combine the fourth material (i.e. the housing 30) and the first surrounding portion 12 with similar materials, or combine the fourth material and the second surrounding portion 22 with similar materials, so as to provide good airtight effect.

The button structure of the wireless transceiver and the manufacturing thereof have the following advantages. A manufacturer may produce the first spring-back button 10 and the second spring-back button 20 by a double injection molding machine in advance, and then combine the first spring-back button 10 and the second spring-back button 20 with the housing 30 by the insert injection molding, so as to make the wireless transceiver with buttons of different colors. The first spring-back button 10 and the second spring-back button 20 can be connected with the housing 30 airtightly, such that the wireless transceiver is waterproof and dustproof. Since the double injection molding and the insert injection molding are normal manufacturing processes, complexity and cost of the machines and molds required for the double injection molding and the insert injection molding are lower than those of the injection molding machines for injecting three materials. Therefore, manufacturing cost of the wireless transceiver can be greatly reduced and the wireless transceiver is capable of meeting the requirement of a predetermined Ingress Protection (IP) rating.

Similarly, to people skilled in the art, under the disclosure or teaching of the present invention, it is also able to manufacture the first spring-back button 10, the second spring-back button 20 and a third spring-back button 40 by the double injection molding in advance. As shown in FIGS. 1 and 2, the third spring-back button 40 is the same as the first spring-back button 10 and the second spring-back button 20 in structure and has at least one third pressing portion, a third surrounding portion disposed around the at least one third pressing portion, and a third elastic connecting portion connecting the at least one third pressing portion and the third surrounding portion. The at least one third pressing portion and the third surrounding portion of the third spring-back button 40 may have a third color, which is different from the first color and the second color.

During manufacturing, a third preparation step 44 is further added between the second preparation step 42 and the assembling step 43 and is substantially the same as the first preparation step 41. The difference between the third preparation step 44 and the first preparation step 41 is the color of the material used. Specifically, in the third preparation step 44, a fourth mold is provided, a fifth material is injected into the fourth mold to form the at least one third pressing portion and the third surrounding portion, and the third material is injected into the fourth mold to form the third elastic connecting portion. The third surrounding portion is disposed around the at least one third pressing portion and the fifth material has a fifth color, which is different from the first color and the second color. The third elastic connecting portion connects the at least one third pressing portion and the third surrounding portion, such that the at least one third pressing portion, the third surrounding portion and the third elastic connecting portion form the third spring-back button 40.

Then in the assembling step 43, the first spring-back button 10, the second spring-back button 20 and the third spring-back button 40 are placed in the third mold, and then the fourth material, which is used for forming the housing 30, is injected into the third mold to form the housing 30 by the insert injection molding. Thus, the housing 30 could have the first, second and third spring-back buttons 10, 20, 40 with different colors without being manufactured by the injection molding machines for injecting three materials. Consequently, manufacturing cost of the wireless transceiver is greatly reduced.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A button structure of a wireless transceiver, and the button structure comprising:
a housing having a first button hole and a second button hole;
a first spring-back button mounted in the first button hole of the housing and having
at least one first pressing portion;
a first surrounding portion disposed around the at least one first pressing portion, wherein the at least one first pressing portion and the first surrounding portion are made of the same material and have a first color; and
a first elastic connecting portion connecting the at least one first pressing portion and the first surrounding portion, wherein the first spring-back button is integrally formed by double injection molding; and
a second spring-back button mounted in the second button hole of the housing and having
at least one second pressing portion;
a second surrounding portion disposed around the at least one second pressing portion, wherein the at least one second pressing portion and the second surrounding portion are made of the same material and have a second color; and
a second elastic connecting portion connecting the at least one second pressing portion and the second surrounding portion, wherein the second spring-back button is integrally formed by double injection molding and the second color and the first color are different colors;
wherein the first spring-back button and the second spring-back button are connected with the housing through insert injection molding.

2. The button structure of the wireless transceiver as claimed in claim 1, wherein the housing has an interior space formed inside the housing for mounting a communication module, and the communication module has
at least one first triggering switch, and each of the at least one first triggering switch corresponding in position to a corresponding one of the at least one first pressing portion; and
at least one second triggering switch, and each of the at least one second triggering switch corresponding in position to a corresponding one of the at least one second pressing portion.

3. The button structure of the wireless transceiver as claimed in claim 1, wherein a material for forming the at least one first pressing portion and the first surrounding portion of the first spring-back button and for forming the at least one second pressing portion and the second surrounding portion of the second spring-back button is a synthetic resin of polycarbonate and acrylonitrile butadiene styrene.

4. The button structure of the wireless transceiver as claimed in claim 2, wherein a material for forming the at least one first pressing portion and the first surrounding portion of the first spring-back button and for forming the at least one second pressing portion and the second surrounding portion of the second spring-back button is a synthetic resin of polycarbonate and acrylonitrile butadiene styrene.

5. The button structure of the wireless transceiver as claimed in claim 1, wherein a material for forming the first elastic connecting portion of the first spring-back button and the second elastic connecting portion of the second spring-back button is thermal plastic rubber.

6. The button structure of the wireless transceiver as claimed in claim 2, wherein a material for forming the first elastic connecting portion of the first spring-back button and the second elastic connecting portion of the second spring-back button is thermal plastic rubber.

7. The button structure of the wireless transceiver as claimed in claim 1, wherein
a color of the first elastic connecting portion is a lighter color of the first color; and
the color of the second elastic connecting portion is a lighter color of the second color.

8. A manufacturing method of a button structure of a wireless transceiver including steps of:
a first preparation step: providing a first mold, injecting a first material into the first mold to form at least one first pressing portion and a first surrounding portion, and injecting a third material into the first mold to form a first elastic connecting portion, wherein the first surrounding portion is disposed around the at least one first pressing portion, the first material has a first color, the first elastic connecting portion connects the at least one first pressing portion and the first surrounding portion, and the at least one first pressing portion, the first surrounding portion and the first elastic connecting portion form a first spring-back button;
a second preparation step: providing a second mold, injecting a second material into the second mold to form at least one second pressing portion and a second surrounding portion, and injecting the third material into the second mold to form a second elastic connecting portion, wherein the second surrounding portion is disposed around the at least one second pressing portion, the second material has a second color, the second color and the first color are different colors, the second elastic connecting portion connects the at least one second pressing portion and the second surrounding portion, and the at least one second pressing portion, the second surrounding portion and the second elastic connecting portion form a second spring-back button; and
an assembling step: providing a third mold, placing the first spring-back button and the second spring-back button in the third mold, and injecting a fourth material into the third mold to form a housing.

9. The manufacturing method of the button structure of the wireless transceiver as claimed in claim 8, wherein the first material is a synthetic resin of polycarbonate and acrylonitrile butadiene styrene.

10. The manufacturing method of the button structure of the wireless transceiver as claimed in claim 8, wherein the second material is a synthetic resin of polycarbonate and acrylonitrile butadiene styrene.

11. The manufacturing method of the button structure of the wireless transceiver as claimed in claim 8, wherein the third material is thermal plastic rubber.

12. The manufacturing method of the button structure of the wireless transceiver as claimed in claim 8, wherein
a third preparation step is further included between the second preparation step and the assembling step, and in the third preparation step: providing a fourth mold, injecting a fifth material into the fourth mold to form at least one third pressing portion and a third surrounding portion, and injecting the third material into the fourth mold to form a third elastic connecting portion, wherein the third surrounding portion is disposed around the at least one third pressing portion, the fifth material has a fifth color, the fifth color, the first color and the second color are different colors, the third elastic connecting portion connects the at least one third pressing portion and the third surrounding portion, and the at least one third pressing portion, the third surrounding portion and the third elastic connecting portion form a third spring-back button; and
in the assembling step: placing the first spring-back button, the second spring-back button and the third spring-back button in the third mold, and injecting the fourth material into the third mold to form the housing.

13. The manufacturing method of the button structure of the wireless transceiver as claimed in claim 8, wherein
a color of the third material is a lighter color of the first color when the third material is used to form the first elastic connecting portion; and
the color of the third material is a lighter color of the second color when the third material is used to form the second elastic connecting portion.
